(19) United States
(12) Patent Application Publication
(10) Pub. No.: US 2018/0364794 A1
(43) Pub. Date: Dec. 20, 2018

(54) METHOD, APPARATUS, AND SYSTEM FOR REDUCING POWER CONSUMPTION OF USB-C INTERFACE

(71) Applicant: Shenzhen Coolhear Information Technology Co., Ltd., Shenzhen, CN (US)

(72) Inventors: Haijun YI, Shenzhen (CN); Bin LI, Shenzhen (CN)

(21) Appl. No.: 16/118,411

(22) Filed: Aug. 30, 2018

Related U.S. Application Data
(63) Continuation-in-part of application No. PCT/CN2017/102332, filed on Sep. 19, 2017.

(30) Foreign Application Priority Data
Apr. 21, 2017 (CN) 201710266867.5

(51) Int. Cl. G06F 1/32; G06F 1/26; H03K 17/95

(52) U.S. Cl. CPC G06F 1/3293; G06F 1/3215; G06F 2213/0042; H03K 17/951; G06F 1/266

(57) ABSTRACT

A method for reducing power consumption of a USB-C interface, including: determining whether an audio and/or video player connected to a mobile terminal including a USB-C interface via the USB-C interface is in an inactive status, if so, switching off the power output of the mobile terminal to the USB-C interface, or reducing the power output of the mobile terminal to the USB-C interface; if not, maintaining the power output of the mobile terminal to the USB-C interface to supply power to the audio and/or video player connected to the mobile terminal via the USB-C interface.

### CROSS-REFERENCE TO RELATED APPLICATIONS

This application is a continuation-in-part of International Patent Application No. PCT/CN2017/102332 with an international filing date of Sep. 19, 2017, designating the United States, now pending, and further claims foreign priority benefits to Chinese Patent Application No. 201710266867.5 filed Apr. 21, 2017. The contents of all of the aforementioned applications, including any intervening amendments thereto, are incorporated herein by reference. Inquiries from the public to applicants or assignees concerning this document or the related applications should be directed to: Matthias Scholl P.C., Attn.: Dr. Matthias Scholl Esq., 245 First Street, 18th Floor, Cambridge, Mass. 02142.

### BACKGROUND

The disclosure relates to the field of USB-C interfaces, and more particularly to a method, apparatus and system of reducing power consumption of a USB-C interface.

USB-C, also known as USB Type-C, is a 24-pin USB connector system, which is distinguished by its two-fold rotational-symmetrical connector.

When a terminal device, such as an audio and/or video player, is connected to a mobile terminal via a USB-C interface, regardless of whether the audio/video player is playing audio/video, the mobile terminal continuously outputs power to the USB-C interface.

### SUMMARY

The disclosure provides a method, apparatus, and system capable of reducing power consumption of a USB-C interface when connected to a mobile terminal.

Disclosed is a method for reducing power consumption of a USB-C interface, the method comprising:
S1: determining whether an audio and/or video player connected to a mobile terminal comprising a USB-C interface via the USB-C interface is in an inactive status, if so, proceeding to S2, and otherwise, proceeding to S3;
S2: switching off the power output of the mobile terminal to the USB-C interface, or reducing the power output of the mobile terminal to the USB-C interface; and
S3: maintaining the power output of the mobile terminal to the USB-C interface to supply power to the audio and/or video player connected to the mobile terminal via the USB-C interface.

Determining whether an audio and/or video player connected to a mobile terminal comprising a USB-C interface via the USB-C interface is in an inactive status can comprise: detecting, by a sensor, whether the audio and/or video player is being worn, if so, determining that the audio and/or video player is in an active status, and otherwise, determining that the audio and/or video player is in an inactive status.

Determining whether an audio and/or video player connected to a mobile terminal comprising a USB-C interface via the USB-C interface is in an inactive status can further comprise:
S11: determining whether power consumption management settings for the audio and/or video player have been enabled, if so, proceeding to S12, and otherwise, proceeding to S3;
S12: recording a time length during which no effective audio-video signal is input to the audio and/or video player;
S13: determining whether the time length in S12 during which no effective audio-video signal is input reaches a predefined time, if so, proceeding to S14, and otherwise, proceeding to S3; and
S14: determining whether there is any touch screen operation on the mobile terminal within the time length, if so, proceeding to S3, and otherwise, proceeding to S2.

Switching off or reducing the power output of the mobile terminal to the USB-C interface can comprise: switching off the power output of the USB-C interface, or, driving, by the mobile terminal, the power circuit of the USB-C interface to a deep sleep mode. In general, the power consumption of the USB-C interface is reduced below 5 milliwatts. Alternatively, the USB-C audio and/or video player can switch to a low power consumption sleep mode through communication control.

The mobile terminal comprising a USB-C interface includes but is not limited to a portable host playback device equipped with a USB-C interface, such as a cell phone, a tablet, or a PC. The device may be called a HOST of the USB interface devices.

The USB-C audio and/or video player includes but is not limited to a slave playback device equipped with a USB-C interface, such as a headset, a display, VR video glasses, an optical VR helmet, or a video player. The device may be called an accessory DEVICE of the USB interface devices, although such an accessory may also comprise an MCU and a master controller).

The power consumption management settings can be performed by a function module dedicated to management of the power supply of the USB-C interface; the function module may be an application software disposed on the mobile terminal and having a switch and time length setting functions adapting to management of power consumption of the USB-C interface, or be a combination of hardware and software disposed on the USB-C audio and/or video player and having a switch and time length setting functions adapting to power consumption management. The switch may be, for example, a graphic setup switch or button in an interface of an APP software running on the mobile terminal or a hardware switch or button on the USB-C audio and/or video player.

The sensor mentioned above may be an infrared proximity sensor for sensing proximity to a body, a capacitive sensor, a Hall sensor, a magnetic sensor, an accelerometer, a photosensor, a pressure-sensitive sensor, a blood oxygen sensor, a heart rate sensor and the like, which serves as means for detecting several variables to determine whether the audio and/or video player has been worn on a human.

In S11, enabling of the power consumption management settings for the audio and/or video player may comprise manually enabling the settings, or enabling the settings through intelligent voice input and intelligent voice recognition by the player.

In S12, recording a time length during which no effective audio-video signal is input to the audio and/or video player can comprise: detecting variations of the time domain and frequency domain of a digital audio-video signal input to the audio and/or video player via the USB-C interface of the audio and/or video player, taking the variations as a basis to determine whether there is no effective audio-video signal input to the audio and/or video player, disposing a digital signal processor (DSP) in the audio and/or video player to monitor the signal output via the USB-C interface of the mobile terminal.

The disclosure further provides an apparatus for reducing power consumption of a USB-C interface, comprising a sensor and an audio and/or video player body. The audio and/or video player body comprises a microcontroller, a power management controller, a USB-C circuit, and an audio-video codec; the sensor, the power manager, the USB-C circuit, and the audio-video codec are connected respectively to the microcontroller; and the microcontroller comprises a sensing and detection module that controls the sensor to detect, and the microcontroller determines whether the audio and/or video player connected to the mobile terminal is being worn based on the result of detection; the sensor detects whether the audio and/or video player is being worn, if so, the microcontroller drives the power manager to maintain the original output power of the USB-C interface, and otherwise, the microcontroller drives the power manager to switch off the power output of the mobile terminal to the USB-C interface or reduce the power output of the mobile terminal to the USB-C interface.

The audio and/or video player body can comprise a magnetic switch or Hall switch and a cover in which magnetic material is provided. When the cover is fitted on the audio and/or video player, the status of the magnetic switch or Hall switch is changed from ON to OFF, or from OFF to ON, and the power status of the USB-C interface is changed accordingly from power on to power off, or from power off to power on.

The audio and/or video player can comprise two symmetric parts in which a magnetic Hall switch or magnetic Hall sensor is provided. The engagement and disengagement of the two symmetric parts controls the switching on and off of the magnetic Hall switch or magnetic Hall sensor, to control the power on or off of the USB-C interface.

The disclosure further provides a system for reducing power consumption of a USB-C interface, comprising a determination unit and a power consumption control unit;

the determination unit is configured to determine whether the audio and/or video player connected to the mobile terminal comprising a USB-C interface via the USB-C interface is in an inactive status; and

the power consumption control unit is configured to switch off the power output of the mobile terminal to the USB-C interface, or reduce the power output of the mobile terminal to the USB-C interface, or maintain the power output of the mobile terminal to the USB-C interface to supply power to the audio and/or video player connected to the mobile terminal via the USB-C interface.

The determination unit can comprise a detection module configured to detect whether the audio and/or video player connected to the mobile terminal via the USB-C is being worn, if so, determine that the audio and/or video player is in an active status, and otherwise, determine that the audio and/or video player is in an inactive status.

The detection module can comprise an infrared proximity sensor, a capacitive sensor, a Hall sensor, a magnetic sensor, an accelerometer, a photosensor, a pressure-sensitive sensor, a blood oxygen sensor, and a heart rate sensor.

The determination unit can further comprise a settings-enabled determination module, a statistical calculation module, a time length determination module, and an operation determination module;

the settings enabled determination module is configured to determine whether the power consumption management settings for the audio and/or video player connected to the mobile terminal via the USB-C are enabled;

the statistical calculation module is configured to statistically calculate a time length during which no effective audio-video signal is input to the audio and/or video player;

the time length determination module is configured to determine whether the time length during which no effective audio-video signal is input reaches a predefined time length; the time length is within a range of several seconds to several hours; and

the operation determination module is configured to determine whether there is any touch screen operation on the mobile terminal within the time length.

When the statistical calculation module calculates the time length and the time length determination module determines the time length, variations of the time domain and frequency domain of a digital audio-video signal input to the audio and/or video player via the USB-C interface of the audio and/or video player are detected and used as a basis to determine whether there is no effective audio-video signal input to the audio and/or video player, and a digital signal processor (DSP) is disposed in the audio and/or video player to monitor the signal output via the USB-C interface of the mobile terminal.

Advantages of the method of reducing power consumption of a USB-C, as well as an apparatus and system capable of reducing power consumption of a USB-C interface as described herein are summarized as follows: the method reduces the power consumption of the USB-C interface, prolongs the service life of the battery of the mobile terminal, and reduces unnecessary energy waste.

### BRIEF DESCRIPTION OF THE DRAWINGS

FIG. 1 is a flow diagram of a method for reducing power consumption of a USB-C interface as described herein;

FIG. 2 is a detailed flow diagram of determining whether an audio and/or video player is in an active status as described herein;

FIG. 3 is a schematic structural view of an apparatus for reducing power consumption of a USB-C interface as described herein;

FIG. 4 is a block diagram of a system for reducing power consumption of a USB-C interface as described herein; and

FIG. 5 is a block diagram of a determination unit as described herein.

### DETAILED DESCRIPTION

To further illustrate, experiments detailing a method for reducing power consumption of a USB-C are described below. It should be noted that the following examples are intended to describe and not to limit the description.

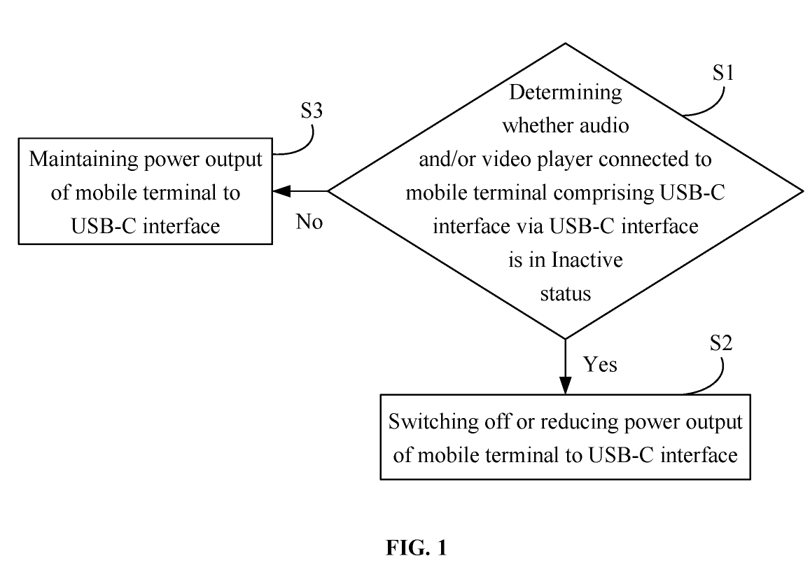

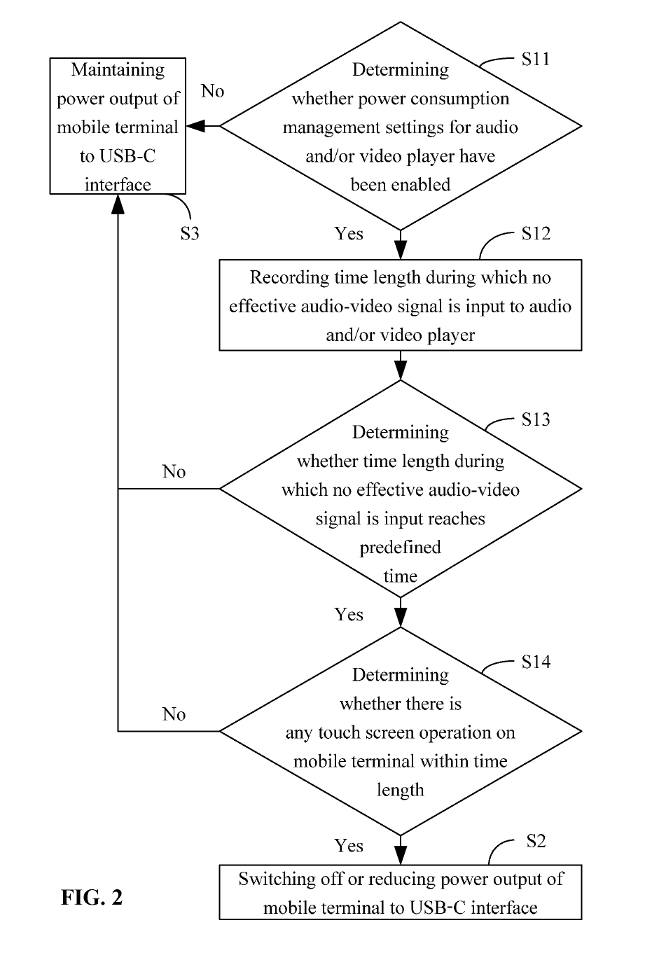

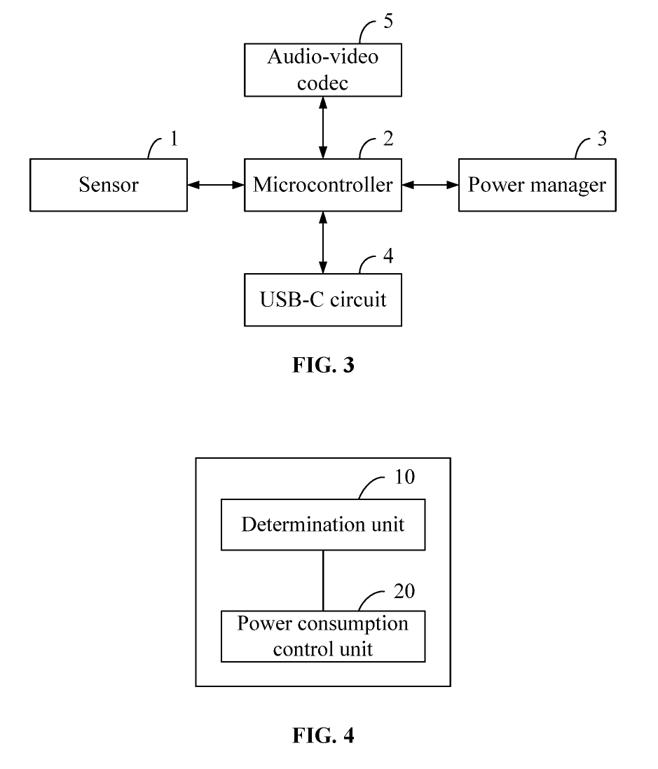

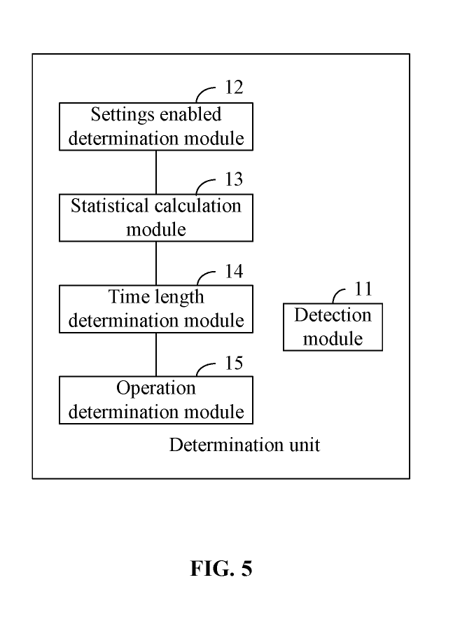

FIGS. 1-5 show a method for reducing power consumption of a USB-C. The method can be applied to an audio and/or video player connected to a mobile terminal via a USB-C interface to solve the problem of the USB-C interface continuously consuming power whenever in use or in nonuse, and continuously draining battery power.

The audio and/or video player connected to a mobile terminal via a USB-C interface includes but is not limited to a headset, a loudspeaker, video glasses, a VR helmet, and other wearable devices.

A method for reducing power consumption of a USB-C comprises the following steps:

S1: determining whether an audio and/or video player connected to a mobile terminal comprising a USB-C interface via the USB-C interface is in an inactive status, if so, proceeding to S2, and otherwise, proceeding to S3;

S2: switching off the power output of the mobile terminal to the USB-C interface, or reducing the power output of the mobile terminal to the USB-C interface; and

S3: maintaining the power output of the mobile terminal to the USB-C interface to supply power to the audio and/or video player connected to the mobile terminal via the USB-C interface.

In step S1, determining whether an audio and/or video player connected to a mobile terminal comprising a USB-C interface via the USB-C interface is in an inactive status comprises: detecting, by a sensor, whether the audio and/or video player is being worn, if so, determining that the audio and/or video player is in an active status, and otherwise, determining that the audio and/or video player is in an inactive status. The mobile terminal comprises a portable master playing device, such as a cell phone, a tablet, or a portable audio player, with a USB-C interface and/or a battery.

The sensor 1 mentioned above may be an infrared proximity sensor 1 for sensing proximity to a body, a capacitive sensor, a Hall sensor, a magnetic sensor, an accelerometer, a photosensor, a pressure-sensitive sensor, a blood oxygen sensor, a heart rate sensor and the like, which serves as means for detecting several variables to determine whether the audio and/or video player has been worn on a human head. When the player has been worn, the power supply is switched on. When the player has been taken off from the head, then a decision is made intelligently to switch off the power supply or reduce the input power of the power supply of the player, or cause the audio and/or video player to enter a deep sleep status.

In addition to using the sensor 1 to detect whether the audio and/or video player is in an inactive status, the detection may be performed by using the following approach. Alternatively, both detection approaches may be used, to improve the accuracy of detection. The above-mentioned S1 of determining whether an audio and/or video player connected to a mobile terminal comprising a USB-C interface via the USB-C interface is in an inactive status further comprises:

S11: determining whether power consumption management settings for the audio and/or video player have been enabled, if so, proceeding to S12, and otherwise, proceeding to S3;

S12: recording a time length during which no effective audio-video signal is input to the audio and/or video player;

S13: determining whether the time length during which no effective audio-video signal is input reaches a predefined time, if so, proceeding to S14, and otherwise, proceeding to S3; and

S14: determining whether there is any touch screen operation on the mobile terminal within the time length, if so, proceeding to S3, and otherwise, proceeding to S2.

In S11, enabling of the power consumption management settings for the audio and/or video player may comprise manually enabling the settings, or enabling the settings through intelligent voice input and intelligent voice recognition by the player.

In S12, recording a time length during which no effective audio-video signal is input to the audio and/or video player comprises: detecting variations of the time domain and frequency domain of a digital audio-video signal input to the audio and/or video player via the USB-C interface of the audio and/or video player, taking the variations as a basis to determine whether there is no effective audio-video signal input to the audio and/or video player, disposing a digital signal processor (DSP) in the audio and/or video player to monitor the signal output via the USB-C interface of the mobile terminal. If it is not audio-video playback data, and no audio-video playback data is detected within a period of time, then the audio and/or video player may be switched off or caused to sleep. Of course, if the audio and/or video player is being used for communication or phone call, then the audio and/or video player will not be switched off or caused to sleep.

In S14, determining whether there is any touch screen operation on the mobile terminal within the time length comprises determining whether the audio-video playback has been stopped or no operation is performed on the mobile terminal over a prolonged period of time. When it is detected that the user has stopped operation/playback of the audio-video software, the audio and/or video player connected to the mobile terminal via the USB-C interface may be paused or enter a low power consumption sleep status, or the power supply of the mobile terminal to the USB-C interface is switched off.

Further, in S2, switching off or reducing the power output of the mobile terminal to the USB-C interface comprises switching off the power output of the USB-C interface of the digital audio-video mobile terminal or driving the USB-C interface of the mobile terminal to enter a low power consumption deep sleep mode.

After the power output of the USB-C interface of the digital audio-video mobile terminal is switched off or the USB-C interface of the mobile terminal is driven to enter a low power consumption deep sleep mode, the power supply to the audio and/or video player may be restarted by manually switching the corresponding power switch or re-plugging to the USB-C interface of the mobile terminal, or alternatively by replaying the audio-video to initiate wakeup from the low power consumption status.

Of course, in certain embodiments, the two approaches described above may be used in combination to detect whether the audio and/or video player is in an inactive status.

The method of the disclosure determines whether an audio and/or video player connected to a mobile terminal comprising a USB-C interface via the USB-C interface is in an inactive status, by means of detection using a sensor, and/or by means of determining whether the power consumption management settings for the audio and/or video player have been enabled, and/or by means of determining whether the time length during which no effective audio-video signal is input reaches a predefined time, and/or by means of determining whether there is any touch screen operation on the mobile terminal within the time length. The output power of the USB-C interface of the mobile terminal is adjusted in accordance with the result of the determination. In this way, solved is the problem of the USB-C interface continuously consuming electric power whenever in use or in nonuse and continuously draining the power of a built-in battery of the player whether or not connected to a mobile terminal. Therefore, the power consumption and energy waste are reduced, the battery life of the cell phone and/or the mobile terminal is prolonged, and the battery lifespan of the cell phone and/or the mobile terminal is extended.

In addition, the disclosure further provides an apparatus for reducing power consumption of a USB-C interface, the apparatus comprising a sensor 1 and an audio and/or video player body. The audio and/or video player body comprises a microcontroller 2, a power management controller 3, a USB-C circuit 4, and an audio-video codec 5. The sensor 1, the power management controller 3, the USB-C circuit 4, and the audio-video codec 5 are respectively connected to the microcontroller 2. The microcontroller 2 comprises a sensing and detection module that controls the sensor to detect. Based on the result of the detection, the microcontroller 2 determines whether the audio and/or video player connected to the mobile terminal is being worn. The sensor 1 detects whether the audio and/or video player body is in the wearing state. If the audio and/or video player is in the wearing state, the microcontroller 2 drives the power manager 3 to maintain the original output power of the mobile terminal to the USB-C interface. If the audio and/or video player body is not in the wearing state, the microcontroller 2 drives the power manager 3 to switch off the output power of the USB-C interface of the mobile terminal or reduce the power output of the USB-C interface by the power supply.

The sensor 1 mentioned above may be an infrared proximity sensor 1 for sensing proximity to a body, a capacitive sensor, a Hall sensor, a magnetic sensor, an accelerometer, a photosensor, a pressure-sensitive sensor, a blood oxygen sensor, a heart rate sensor and the like, which serves as means for detecting several variables to determine whether the audio and/or video player has been worn on a human head. When the player is being worn, the power supply is switched on. When the player is taken off from the head, then the power supply is switched off or the input power of the power supply of the player is reduced, or the audio and/or video player is caused to enter a deep sleep status.

In another embodiment, the audio and/or video player body equipped with a USB-C interface comprises a magnetic switch or Hall switch and a cover in which magnetic material is provided. When the cover is fitted on the audio and/or video player, the status of the magnetic switch or Hall switch is changed from ON to OFF, or from OFF to ON, and the power status of the USB-C interface is changed accordingly from power on to power off, or from power off to power on. In another embodiment, if the USB-C audio and/or video player comprises two symmetric parts, a magnetic Hall switch or magnetic Hall sensor is disposed in the two symmetric parts. When the two symmetric parts are engaged or disengaged, the ON-OFF status of the magnetic Hall switch is changed, and the power status of the USB-C interface is changed accordingly. For example, for a USB-C audio and/or video player consisting of two earpieces arranged symmetrically, when the two earpieces are engaged, the power supply of the USB-C interface is switched off, whereas when the two earpieces are disengaged, the power supply of the USB-C interface remains in its original status.

With the apparatus for reducing power consumption of a USB-C interface described above, the sensor 1 is used to detect whether the audio and/or video player is in an inactive status. In this way, solved is the problem of the USB-C interface continuously consuming electric power whenever in use or in nonuse and continuously draining the power of a built-in battery of the player whether or not connected to a mobile terminal. Therefore, the power consumption and energy waste are reduced, the battery life of the cell phone and/or the mobile terminal is prolonged, and the battery lifespan of the cell phone and/or the mobile terminal is extended.

The disclosure provides a system for reducing power consumption of a USB-C interface, the system comprising a determination unit 10 and a power consumption control unit 20.

The determination unit 10 is configured to determine whether the audio and/or video player connected to the mobile terminal via the USB-C interface is in an inactive status.

The power consumption control unit 20 is configured to switch off the power output of the mobile terminal to the USB-C interface, or reduce the power output of the mobile terminal to the USB-C interface, or maintain the power output of the mobile terminal to the USB-C interface to supply power to the audio and/or video player connected to the mobile terminal via the USB-C interface.

The power consumption control unit 20 described above comprises essentially drive and communication control modules for hardware interfaces, such as the USB-C interface of the mobile terminal, a communication interface, and a power consumption control circuit interface, to provide functions such as audio-video digital/analog converter configuration, sampling setup control for the sensor 1, mobile terminal power management switching, and sleep and wakeup. The communication control module comprises implementations of a communication protocol between the mobile terminal and the digital audio and/or video player, to provide functions such as volume regulation control, switching between playback and phone call, video resolution switching, audio-video data transmission and reception, and control data transmission and reception.

The power consumption control unit 20 switches off or reduce the output power of the USB-C interface of the mobile terminal by switching off the power output of the USB-C interface of the mobile terminal or controlling through communication the audio and/or video player connected via the USB-C interface of the mobile terminal to enter a low power consumption deep sleep mode. After the output power of the USB-C interface of the mobile terminal is switched off or the audio and/or video player connected via the USB-C interface is controlled through communication to enter a low power consumption deep sleep mode and consequently the USB-C interface of the mobile terminal is driven to enter a low power consumption deep sleep mode, the power supply of the audio and/or video player may be restarted by manually pressing a button or toggle a switch on the audio and/or video player or re-plugging to the USB-C interface of the mobile terminal, or alternatively by replaying the audio-video to initiate wakeup of the audio and/or video player from the low power consumption status.

The determination unit 10 described above comprises a detection module 11 configured to detect whether the audio and/or video player connected to the mobile terminal is being worn, and if so, the audio and/or video player is determined to be in an active status, otherwise, the audio and/or video player is determined to be in an inactive status.

The detection module 11 described above may be an infrared proximity sensor 1 for detecting proximity to a body, a capacitive sensor 1, a Hall sensor, a magnetic sensor 1, an accelerometer, a photosensor 1, a pressure-sensitive sensor 1, a blood oxygen sensor, a heart rate sensor and the like that serves as a sensing means for detecting whether the audio and/or video player has been worn on a human head. If the audio and/or video player has been worn, then the power supply is switched on, whereas if the audio and/or video player has been taken off from the head, then a decision is made intelligently to switch off the power supply.

In addition to the sensor 1, the determination unit 10 may further comprise a settings-enabled determination module 12, a statistical calculation module 13, a time length determination module 14, and an operation determination module 15 for the purpose of detection.

The settings enabled determination module 12 is configured to determine whether the power consumption management settings for the USB-C audio and/or video player on the mobile terminal have been enabled.

The statistical calculation module 13 is configured to statistically calculate a time length during which no effective audio-video signal is input to the audio and/or video player.

The time length determination module 14 is configured to determine whether the time length during which no effective audio-video signal is input reaches a predefined time.

The operation determination module 15 is configured to determine whether there is any touch screen operation on the mobile terminal within the time length.

When the statistical calculation module 13 calculates the time length and the time length determination module 14 determines the time length, variations of the time domain and frequency domain of a digital audio-video signal input to the audio and/or video player via the USB-C interface of the audio and/or video player are detected and used as a basis to determine whether there is no effective audio-video signal input to the audio and/or video player, and a digital signal processor (DSP) is disposed in the audio and/or video player to monitor the signal output via the USB-C interface of the mobile terminal. If it is not valid audio-video playback data, and no valid audio-video playback data is detected within a period of time, then the audio and/or video player may be switched off or caused to sleep. Of course, if the audio and/or video player is being used for phone call or video communication, the audio and/or video player will not be switched off or caused to sleep.

In addition, in another embodiment, the system for reducing power consumption of a digital interface audio and/or video player described above further comprises an audio-video playing unit which is a software installed and run on a device, such as a mobile terminal, a portable player, or a laptop computer, with a USB-C interface for playing on-line audio-video or local audio-video and provides audio-video communication acquisition and authentication, decoding and playback, and acquisition and caching of audio-video streams.

In another embodiment, the system for reducing power consumption of a digital interface audio and/or video player described above further comprises a power consumption control circuit unit comprising a microcontroller 2, a sensor 1, a mobile phone equipped with USB-C interface, a sampling control circuit, an audio and/or video player decoding and driving circuit, and a power consumption control circuit. With this system, the information is acquired by the microcontroller from the sensor 1, based on which determination is made depending on the configured conditions. The power consumption control unit 20 controls the power consumption control circuit unit based on the result of the determination, thereby achieving reasonable reduction in the power consumption of the system.

In the system for reducing power consumption of a USB-C interface, the determination unit 10 determines whether the audio and/or video player is in an inactive status. The power consumption control unit 20 controls the output power of the USB-C interface of the mobile terminal in accordance with the result of the determination. In this way, solved is the problem of the USB-C interface continuously consuming electric power whenever in use or in nonuse and continuously draining the power of a built-in battery of the player whether or not connected to a mobile terminal. Therefore, the power consumption and energy waste are reduced, the battery life of the cell phone and/or the mobile terminal is prolonged, and the battery lifespan of the cell phone and/or the mobile terminal is extended.

It will be obvious to those skilled in the art that changes and modifications may be made, and therefore, the aim in the appended claims is to cover all such changes and modifications.

What is claimed is:

1. A method, comprising:
S1: determining whether an audio and/or video player connected to a mobile terminal comprising a USB-C interface via the USB-C interface is in an inactive status, when it is in an active status, proceeding to S2, and if it is not in an active status, proceeding to S3;
S2: switching off the power output of the mobile terminal to the USB-C interface, or reducing the power output of the mobile terminal to the USB-C interface; and
S3: maintaining the power output of the mobile terminal to the USB-C interface to supply power to the audio and/or video player connected to the mobile terminal via the USB-C interface;
wherein
in S1, determining whether an audio and/or video player connected to a mobile terminal comprising a USB-C interface via the USB-C interface is in an inactive status comprises: detecting, by a sensor, whether the audio and/or video player is being worn, if so, determining that the audio and/or video player is in an active status, and otherwise, determining that the audio and/or video player is in an inactive status.

2. The method of claim 1, wherein in S1, determining whether an audio and/or video player connected to a mobile terminal comprising a USB-C interface via the USB-C interface is in an inactive status further comprises:
S11: determining whether power consumption management settings for the audio and/or video player have been enabled, if so, proceeding to S12, and otherwise, proceeding to S3;
S12: recording a time length during which no effective audio-video signal is input to the audio and/or video player;
S13: determining whether the time length during which no effective audio-video signal is input reaches a predefined time, if so, proceeding to S14, and otherwise, proceeding to S3; and
S14: determining whether there is any touch screen operation on the mobile terminal within the time length, if so, proceeding to S3, and otherwise, proceeding to S2.

3. The method of claim 2, wherein in S2, switching off or reducing the power output of the mobile terminal to the USB-C interface comprises: switching off the power output of the USB-C interface, or, driving, by the mobile terminal, the power circuit of the USB-C interface to a deep sleep mode.

4. The method of claim 3, wherein a power consumption of the USB-C interface in the deep sleep mode is below 5 milliwatts.

5. The method of claim 1, wherein the mobile terminal is a portable host playback device equipped with a USB-C interface.

6. The method of claim 5, wherein the mobile terminal comprises a cell phone, a tablet, and a PC.

7. The method of claim 1, wherein the sensor comprises an infrared proximity sensor, a capacitive sensor, a Hall sensor, a magnetic sensor, an accelerometer, a photosensor, a pressure-sensitive sensor, a blood oxygen sensor, and a heart rate sensor.

8. The method of claim 2, wherein in S11, the power consumption management settings for the audio and/or video player are enabled manually, or through intelligent voice input and recognition.

9. The method of claim 2, wherein in S12, recording a time length during which no effective audio-video signal is input to the audio and/or video player comprises: detecting variations of the time domain and frequency domain of a digital audio-video signal input to the audio and/or video player via the USB-C interface of the audio and/or video player, taking the variations as a basis to determine whether there is no effective audio-video signal input to the audio and/or video player, disposing a digital signal processor (DSP) in the audio and/or video player to monitor the signal output via the USB-C interface of the mobile terminal.

10. An apparatus, comprising: a sensor and an audio and/or video player body; wherein:
the audio and/or video player body comprises a microcontroller, a power management controller, a USB-C circuit, and an audio-video codec;
the sensor, the power manager, the USB-C circuit, and the audio-video codec are connected respectively to the microcontroller;
the microcontroller comprises a sensing and detection module that controls the sensor to operate;
the sensor is configured to detect whether the audio and/or video player is being worn, if so, the microcontroller drives the power manager to maintain the original output power of the USB-C interface, and otherwise, the microcontroller drives the power manager to switch off the power output of the mobile terminal to the USB-C interface or reduce the power output of the mobile terminal to the USB-C interface.

11. The apparatus of claim 10, wherein the mobile terminal is a portable host playback device equipped with a USB-C interface.

12. The apparatus of claim 11, wherein the mobile terminal comprises a cell phone, a tablet, and a PC.

13. The apparatus of claim 10, wherein the sensor comprises an infrared proximity sensor, a capacitive sensor, a Hall sensor, a magnetic sensor, an accelerometer, a photo-sensor, a pressure-sensitive sensor, a blood oxygen sensor, and a heart rate sensor.

14. The apparatus of claim 10, wherein the audio and/or video player body comprises a magnetic switch or Hall switch and a cover, and magnetic material is disposed in the cover; when the cover is fitted on the audio and/or video player, the status of the magnetic switch or Hall switch is changed from ON to OFF, or from OFF to ON, and the power status of the USB-C interface is changed accordingly from power on to power off, or from power off to power on.

15. The apparatus of claim 10, wherein the audio and/or video player comprises two symmetric parts in which a magnetic Hall switch or magnetic Hall sensor is provided; the engagement and disengagement of the two symmetric parts controls the switching on and off of the magnetic Hall switch or magnetic Hall sensor, to control the power on or off of the USB-C interface.

16. A system, comprising: a determination unit and a power consumption control unit;
wherein:
the determination unit is configured to determine whether the audio and/or video player connected to the mobile terminal comprising a USB-C interface via the USB-C interface is in an inactive status; and
the power consumption control unit is configured to switch off the power output of the mobile terminal to the USB-C interface, or reduce the power output of the mobile terminal to the USB-C interface, or maintain the power output of the mobile terminal to the USB-C interface to supply power to the audio and/or video player connected to the mobile terminal via the USB-C interface.

17. The system of claim 16, wherein the determination unit comprises a detection module configured to detect whether the audio and/or video player connected to the mobile terminal via the USB-C is being worn, if so, determine that the audio and/or video player is in an active status, and otherwise, determine that the audio and/or video player is in an inactive status.

18. The system of claim 17, wherein the detection module comprises an infrared proximity sensor, a capacitive sensor, a Hall sensor, a magnetic sensor, an accelerometer, a photosensor, a pressure-sensitive sensor, a blood oxygen sensor, and a heart rate sensor.

19. The system of claim 17, wherein:
the determination unit further comprises a settings-enabled determination module, a statistical calculation module, a time length determination module, and an operation determination module;
the settings enabled determination module is configured to determine whether the power consumption management settings for the audio and/or video player connected to the mobile terminal via the USB-C are enabled;
the statistical calculation module is configured to statistically calculate a time length during which no effective audio-video signal is input to the audio and/or video player;
the time length determination module is configured to determine whether the time length during which no effective audio-video signal is input reaches a predefined time length; the time length is within a range of several seconds to several hours; and
the operation determination module is configured to determine whether there is any touch screen operation on the mobile terminal within the time length.

20. The system of claim 19, wherein when the statistical calculation module calculates the time length and the time length determination module determines the time length, variations of the time domain and frequency domain of a digital audio-video signal input to the audio and/or video player via the USB-C interface of the audio and/or video player are detected and used as a basis to determine whether there is no effective audio-video signal input to the audio and/or video player, and a digital signal processor (DSP) is disposed in the audio and/or video player to monitor the signal output via the USB-C interface of the mobile terminal.
